(19) United States
(12) Patent Application Publication
(10) Pub. No.: US 2005/0274966 A1
(43) Pub. Date: Dec. 15, 2005

(54) Fuse and write method for fuse

(75) Inventor: Tomohiro Matsunaga, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/117,330

(22) Filed: Apr. 29, 2005

(30) Foreign Application Priority Data
Jun. 10, 2004 (JP) 2004-293444

(51) Int. Cl. H01L 33/00

(52) U.S. Cl. 257/96

(57) ABSTRACT

A polysilicon fuse includes a fusing part to be fused through voltage application, a positive terminal side joint connected to one end of the fusing part and a negative terminal side joint connected to the other end of the fusing part. The positive terminal side joint that attains a high voltage through the voltage application has lower resistance and higher heat conductivity than the negative terminal side joint. Furthermore, a write operation is performed, with a current limiting resistance serially connected to a positive terminal side joint of a polysilicon fuse, by applying a voltage pulse to the polysilicon fuse through the current limiting resistance. Thus, a current flowing to the polysilicon fuse in fusing the fusing part is limited to a given range.

### CROSS-REFERENCE TO RELATED APLICATIONS

This application claims priority under 35 U.S.C. §119 on Patent Application No. 2004-293444 filed in Japan on Oct. 6, 2004, the entire contents of which are hereby incorporated by reference.

### BACKGROUND OF THE INVENTION

The present invention relates to a fuse, and more particularly, it relates to a fuse in which a write current and a write voltage are reduced and a write method for a fuse in which a write current can be reduced.

A conventionally used fuse, such as a polysilicon fuse, includes a fusing part that is fused through voltage application; a positive terminal side joint that is connected to one end of the fusing part and to which a voltage is applied; and a negative terminal side joint connected to the other end of the fusing part. The positive terminal side joint and the negative terminal side joint have the same structure and the same property.

In a polysilicon fuse, one of some kinds of structures is used for the positive terminal side joint and the negative terminal side joint (which are hereinafter simply referred to together as the joint). For example, the joint has a structure using a polysilicon layer in the same manner as in the fusing part, and alternatively, the joint has a structure with low resistance using a polysilicon layer and a silicide layer for reducing a write voltage applied for fusing. Alternatively, the joint has a structure with low resistance using a polysilicon layer, an interconnect layer and a contact for connecting the polysilicon layer and the interconnect layer to each other.

Now, a conventional polysilicon fuse will be described in detail with reference to the accompanying drawings.

FIGS. 11A and 11B are diagrams for showing an example (hereinafter referred to as Conventional Example 1) of a semiconductor device including a conventional polysilicon fuse, and specifically, FIG. 11A is a plan view in which the polysilicon fuse 10 alone is perspectively shown and FIG. 11B is a cross-sectional view taken on line XIb-XIb′ of FIG. 11A.

As shown in FIG. 11A, the polysilicon fuse 10 includes a fuse layer 11, an interconnect layer 12 and contacts 13 for electrically connecting the fuse layer 11 and the interconnect layer 12 to each other.

The fuse layer 11 is composed of a fusing part 11a that is fused through voltage application and connecting parts 11b connected to the fusing part 11a, and at least a portion of each connecting part 11b positioned on the other side of the fusing part 11a is used as an interconnect region (not shown) to be connected to the interconnect layer 12.

Also, the connecting part 11b, the interconnect layer 12 disposed on the connecting part 11b and the contacts 13 together form a joint 14. At this point, a part of the joint 14 disposed on the side to which a voltage is applied through an interconnect (not shown) corresponds to a positive terminal side joint 14a and the other part of the joint 14 corresponds to a negative terminal side joint 14b.

Furthermore, an interconnect (not shown) is connected to the polysilicon fuse 10, so that a voltage can be applied thereto.

The connecting part 11b has a width, for example, four or more times as large as that of the fusing part 11a, and is in a taper shape narrowed toward the fusing part 11a in the vicinity of the fusing part 11a.

Next, as shown in the cross-sectional view of FIG. 11B, the semiconductor device including the conventional polysilicon fuse 10 is composed of a substrate 21, a thermal oxidation film 22 formed on the substrate 21, the fuse layer 11 formed on the thermal oxidation film 22, the interconnect layer 12 for applying a voltage to the fuse layer 11 and the contacts 13 for connecting the fuse layer 11 and the interconnect layer 12 to each other. Also, an interlayer insulating film 23 is formed above the thermal oxidation film 22 so as to cover the fuse layer 11, the interconnect layer 12 and the contacts 13, and a passivation film 24 is formed on the interlayer insulating film 23.

Furthermore, a semiconductor device including a conventional polysilicon fuse 20 according to another conventional example (hereinafter referred to as Conventional Example 2) is shown in FIGS. 12A and 12B. The structure of the semiconductor device of Conventional Example 2 is different from that of Conventional Example 1 in the interconnect layer 12 formed over the connecting parts 11b (in other words, the whole connecting parts 11b are used as the interconnect region).

Since this structure is employed in the semiconductor device of Conventional Example 2, a current can flow in the interconnect layer 12 having lower resistance than the fuse layer 11 made of polysilicon, and therefore, the resistance of the joint 14 composed of the interconnect layer 12, the connecting part 11b and the contacts 13 is lowered.

The rest of the structure of Conventional Example 2 is the same as that of Conventional Example 1 and hence the detailed description is omitted with the same reference numerals as those shown in FIGS. 11A and 11B used.

Also, FIG. 13 is a diagram for showing the configuration of a PROM (programmable read only memory) circuit 31 using the polysilicon fuse 10 and a write circuit 32 for performing a write operation by fusing the polysilicon fuse 10 corresponding to each bit of the PROM circuit 31.

The PROM circuit 31 includes a plurality of polysilicon fuses 10 and a plurality of driving transistors 41 for selecting a polysilicon fuse 10 to be fused and applying a write current to the selected polysilicon fuse 10.

The write circuit 32 includes a protective resistance 42 and a relay 43 for connecting the PROM circuit 31 to the write circuit 32, and further includes a stray capacitance 44 accompanying the relay 43 or the like. In general, the stray capacitance 44 has capacity of approximately 1 through 10 pF, and it is very difficult to make it 0 (zero).

Next, an operation for fusing the polysilicon fuse of Conventional Example 1 shown in FIGS. 11A and 11B in the circuit configuration shown in FIG. 13 will be described.

In a write operation for the polysilicon fuses 10 included in the PROM circuit 31, a polysilicon fuse 10 to be written is selected by the corresponding driving transistor 41, and a voltage pulse P is applied to the selected polysilicon fuse 10 by the write circuit 32.

At this point, the voltage pulse P has a given rise time constant, a given voltage value, a given pulse time and the like.

Herein, the resistance of the conventional polysilicon fuse 10 is indicated by R and the resistance of the joint 14 and the fusing part 11a out of the resistance R are respectively indicated by Rj and Rc. In other words, R=2Rj+Rc.

Furthermore, a voltage applied for fusing to the positive terminal side joint of the polysilicon fuse 10 is indicated by Vc and the negative terminal side joint is assumed to be grounded (through the corresponding driving transistor 41).

In this case, a current Ic flowing to the polysilicon fuse 10 is represented as follows:
Ic=Vc/R=Vc/(2·Rj+Rc)

When the voltage pulse P is applied, the current Ic is increased as the voltage Vc increases, and hence Joule heat is generated in the fusing part 11a. Thus, the internal temperature of the fusing part 11a is increased.

In the case where the heat radiation effect of the joint 14 is small or the fusing part 11a is short, the temperature distribution in the fusing part 11a has a peak in a position shifted from the center of the fusing part 11a toward the positive terminal side joint 14a.

On the contrary, in the case where the heat radiation effect of the joint 14 is large or the fusing part 11a is long, the temperature distribution in the fusing part 11a has a peak at the center of the fusing part 11a.

At this point, when the temperature in the position corresponding to the peak of the temperature distribution reaches 1410° C., that is, the melting point of Si, a part of the polysilicon included in the fuse layer 11 is melted into a liquid form, and a structure designated as a filament is formed within the fusing part 11a. The electric resistance of the fusing part 11a is, for example, approximately 500 through 1000 Ω while the electric resistance of the filament is, for example, approximately several tens Ω. Therefore, when the filament is formed, the resistance R of the polysilicon fuse 10 is abruptly lowered, and accordingly the voltage Vc is also temporarily reduced. When this reduction of the voltage Vc is indicated by ΔVc, the reduced voltage ΔVc is larger as the resistance R of the polysilicon fuse 10 is more largely lowered as a result of the formation of the filament.

When the voltage Vc is lowered, the stray capacitance 44 discharges a current. More specifically, when the voltage Vc is lowered by the voltage ΔVc, the stray capacitance 44 discharges a discharge current ΔIc=≢Vc/R=ΔVc/(2·Rj+Rc). Thus, the discharge current ΔIc is applied to the polysilicon fuse 10.

In other words, not only the current Ic (=Vc/R=Vc/(2·Rj+Rc)) derived from the voltage pulse applied for fusing but also the discharge current ΔIc (=ΔVc/R=ΔVc/(2·Rj+Rc)) from the stray capacitance 44 is applied to the polysilicon fuse 10.

In this manner, the current flowing to the polysilicon fuse 10 when the filament is formed is Vc/(2·Rj+Rc)+ΔVc/(2·Rj+Rc), namely, the current is abruptly increased in forming the filament.

The filament formed in the fusing part 11a grows within the fusing part Ha in the width direction and the thickness direction. Ultimately, the filament is fissioned and fused in the position corresponding to the peak of the temperature distribution of the fusing part 11a owing to the surface tension of the filament itself and film stress applied to the fuse layer 11.

As the related arts of this invention, for example, Japanese Patent No. 3239448 (FIG. 1 in particular), Japanese Laid-Open Patent Publication No. 57-120362 (FIG. 1 in particular) and “The Physics and Reliability of Fusing Polysilicon” (A. Ito, E. W. (Pete) George, R. K. Lowry, H. A. Swasey, IEEE IRPS, (1984) 17) are known.

### SUMMARY OF THE INVENTION

The conventional polysilicon fuse has, however, the following problems:

In using the PROM circuit using the polysilicon fuse, the BVCES (breakdown voltage collector emitter short) of the driving transistor 41 should be larger than the write voltage. Therefore, in a process where the BVCES of the driving transistor 41 is low, it is necessary to lower the write voltage. In using the conventional polysilicon fuse, however, when the write voltage is lowered, the write current becomes large. This will now be described.

In the polysilicon fuse of Conventional Example 1, each of the two joints 14 (i.e., the positive terminal side joint 14a and the negative terminal side joint 14b) has the resistance Rj (which depends upon the sheet resistance of the fuse layer 11 made of polysilicon).

Therefore, in the case where the write voltage is applied to the polysilicon fuse 10 for fusing the fusing part 11a and the current Ic flows, voltage drop corresponding to 2·Rj·Ic in total is caused in the two joints 14. In other words, under application of the write voltage to the polysilicon fuse 10, the voltage applied to the both ends of the fusing part 11a is lowered by a voltage corresponding to 2·Rj·Ic.

Since it is necessary to lower the write voltage as described above, the length of the fusing part 11a may be reduced in order to enable a write operation in such a case. However, when the length is reduced, the peak of the temperature distribution in the fusing part 11a obtained under voltage application is shifted toward the positive terminal side joint 14a in the fusing part 11a.

In the case where the heat conductivity of the joint 14 is low because of a small width of the joint 14 or the like, a part of the positive terminal side joint 14a may be melted due to the heat generated in the fusing part 11a. The write current, that is, a current flowing to the polysilicon fuse 10 in writing, is increased in proportion to the cross-sectional area of a melted portion. Therefore, when the joint 14 having a cross-section larger than the fusing part 11a is melted, the write current is unavoidably increased.

Next, the problem of the polysilicon fuse 20 of Conventional Example 2 in which the interconnect layer 12 is formed over the connecting part 11b and the interconnect layer 12 and the connecting part 11b are connected to each other through the contacts 13 will be described.

In this case, the resistance Rj of the joint 14 is lowered to, for example, approximately several Ω, which can be approximated to 0 (zero) because it is sufficiently smaller than the resistance Rc of the fusing part 11a. Therefore, differently from the polysilicon fuse of Conventional Example 1, there is no need to reduce the length of the fusing part 11a. Also, since the interconnect layer 12 having higher heat conductivity than the fuse layer 11 is formed over the connecting part 11b, the efficiency in the heat radiation from the joint 14 is improved.

Accordingly, in the case where the write voltage is applied to the polysilicon fuse 20 of Conventional Example 2, the peak of the temperature distribution in the fusing part 11a is positioned at the center of the fusing part 11a, and hence, the fusing part 11a alone is fused. However, since the resistance Rj of the joint 14 is so low that it can be approximated to 0 as compared with the resistance Rc of the fusing part 11a, when the filament is formed, the resistance R of the polysilicon fuse 20, which was 500 through 1000 Ωbefore the formation of the filament, is lowered to approximately several tens Ω. At the same time, the voltage Vc applied to the positive terminal side joint of the polysilicon fuse 20 is lowered, and hence, large voltage drop ΔVc is caused.

As a result, in fusing the polysilicon fuse of Conventional Example 2, the discharge current ΔVc/Rc from the stray capacitance 44 is increased, and the current Ic flowing to the polysilicon fuse 20 becomes extremely large (for example, becomes approximately 120 mA when the sheet resistance of polysilicon is 200 Ω/□ and the width of polysilicon is 0.8 μm).

In this manner, in the conventional technique, when the resistance of the joint 14 is substantially reduced or the length of the fusing part 11a is reduced for lowering the write voltage, the write current is increased. When the write current is increased, it is necessary to increase the cell area of the driving transistor 41. In other words, in the case where the PROM circuit using the polysilicon fuse is applied to a process where the BVCES is low, the chip area is unavoidably increased.

This is one problem of the conventional technique.

Also, in the write circuit 32 and the PROM circuit 31 shown in FIG. 13, the write voltage and the write current are determined depending upon the structure of the fuse. In other words, the write current cannot be reduced by, for example, adjusting a constant of the write circuit 32. This is another problem of the conventional technique.

In consideration of the aforementioned conventional problems, an object of the invention is reducing both a write voltage and a write current in a fuse. Another object of the invention is reducing a write current in a write method for a fuse. Thus, increase of the chip area of a PROM circuit or the like using a fuse is prevented.

In order to achieve the object, the fuse of this invention includes a fusing part to be fused through voltage application; a positive terminal side joint connected to one end of the fusing part; and a negative terminal side joint connected to the other end of the fusing part, and the positive terminal side joint and the negative terminal side joint are different from each other in at least one of a structure and a property.

In the fuse of this invention, the fusing part is narrower than the positive terminal side joint and the negative terminal side joint, and hence, when a voltage is applied to: the fuse, the fusing part is fused.

In the fuse of this invention, the structures and the properties of the positive terminal side joint and the negative terminal side joint are individually set. Therefore, for example, the position of a peak of the temperature distribution in the fusing part attained in fusing can be adjusted. As a result, the fusing part alone can be fused without melting a part of the positive terminal side joint by, for example, adjusting the temperature peak to be positioned at the center of the fusing part. Therefore, increase of a write current otherwise caused in forming a filament can be prevented. Specifically, this effect can be realized by, for example, setting the structure of the positive terminal side joint to have low resistance. Also, even when the length of the fusing part is reduced for lowering a write voltage, the peak of the temperature distribution is not shifted toward the positive terminal side joint, and therefore, the increase of the write current derived from melting of the positive terminal side joint can be prevented, resulting in remarkably exhibiting the effect of the invention.

Furthermore, since both the write voltage and the write current can be reduced, when the fuse of this invention is used in, for example, a PROM circuit, increase of a cell area of a driving transistor can be prevented, resulting in preventing the increase of the whole chip area.

In one aspect, the positive terminal side joint preferably has higher heat conductivity than the negative terminal side joint.

Herein, the heat conductivity means the heat conductivity of the whole positive terminal side joint and that of the whole negative terminal side joint.

In this manner, since the positive terminal side joint has higher heat conductivity and a larger heat radiation effect, the peak of the temperature distribution in the fusing part attained in fusing can be definitely prevented from shifting toward the positive terminal side joint. Accordingly, as described above, the positive terminal side joint can be prevented from being partly melted, resulting in preventing the increase of the write current.

In another aspect, the positive terminal side joint preferably has lower resistance than the negative terminal side joint.

In this manner, Joule heat generated in the positive terminal side joint is reduced, and therefore, the peak of the temperature distribution in the fusing part attained in fusing can be prevented from shifting toward the positive terminal side joint. Accordingly, as described above, the increase of the write current can be prevented. Also, since the negative terminal side joint has given resistance higher than the positive terminal side joint, as compared with the conventional technique in which the resistances of both the positive terminal side joint and the negative terminal side joint are reduced, an excessive current can be prevented from flowing when a filament is formed in fusing.

Also, when the heat conductivity of the positive terminal side joint is higher than that of the negative terminal side joint and the resistance of the positive terminal side joint is lower than that of the negative terminal side joint, the effects of the respective cases are both attained. Accordingly, the effect of the invention to reduce the write voltage and the write current can be more remarkably attained.

In one aspect, the positive terminal side joint preferably has a larger width than the negative terminal side joint. Also, the area of the positive terminal side joint is preferably larger than that of the negative terminal side joint.

Thus, the resistance of the positive terminal side joint can be made lower than that of the negative terminal side joint. Also, since the heat conductivity is higher as the area is larger, the heat conductivity of the positive terminal side joint can be made higher than that of the negative terminal side joint.

Accordingly, the effect of the invention can be definitely attained.

In one aspect, the positive terminal side joint preferably has a larger width at least in a region in the vicinity of the fusing part than the negative terminal side joint.

Also in this manner, the positive terminal side joint can attain lower resistance and higher heat conductivity (a larger heat radiation effect) than the negative terminal side joint as in the case where the width of the whole positive terminal side joint is larger than that of the negative terminal side joint. Accordingly, the effect of the invention can be definitely attained.

Specifically, for example, the positive terminal side joint is in a taper shape that is linearly tapered toward the fusing part from a position away by a given distance from the fusing part. On the contrary, the negative terminal side joint is in a shape, for example, obtained by dropping arc-shaped areas out of a taper shape similar to the taper shape of the positive terminal side joint.

Preferably, the fusing part, a positive terminal side connecting part that is a portion of the positive terminal side joint connected to the fusing part and a negative terminal side connecting part that is a portion of the negative terminal side joint connected to the fusing part are formed in an identical fuse layer, the positive terminal side joint includes the positive terminal side connecting part, a positive terminal side interconnect layer formed above the positive terminal side connecting part and at least one positive terminal side contact for connecting the positive terminal side connecting part and the positive terminal side interconnect layer to each other, and the negative terminal side joint includes the negative terminal side connecting part, a negative terminal side interconnect layer formed above the negative terminal side connecting part and at least one negative terminal side contact for connecting the negative terminal side connecting part and the negative terminal side interconnect layer to each other.

Thus, the effect of the invention is attained in a fuse composed of a fuse layer including a fusing part and an interconnect layer for applying a voltage to the fuse layer.

Preferably, the fuse layer is made of polysilicon.

Thus, the effect of the invention is attained in a polysilicon fuse.

In one aspect, the positive terminal side contact preferably has a larger area than the negative terminal side contact. For example, a single positive terminal side contact and a single negative terminal side contact are formed with the area of the positive terminal side contact set to be larger than that of the negative terminal side joint. Alternatively, a plurality of positive terminal side contacts and a plurality of negative terminal side contacts respectively having the same area are formed with the number of positive terminal side contacts set to be larger than that of negative terminal side contacts. Also in this case, the whole area of the positive terminal side contacts is larger than the whole area of the negative terminal side contacts.

In this manner, the resistance of the positive terminal side joint can be definitely made lower than that of the negative terminal side joint.

Furthermore, the interconnect layer and the contacts are made of a material generally having higher heat conductivity than an interlayer insulating film or the like formed for covering the fuse when the fuse is incorporated in a semiconductor device. Therefore, the heat conductivity of the positive terminal side joint can be made higher than that of the negative terminal side joint and the heat radiation effect of the positive terminal side joint can be made larger than that of the negative terminal side joint.

Accordingly, the effect of the invention can be definitely attained by employing the aforementioned structure.

In one aspect, the positive terminal side joint preferably further includes a silicide layer formed at least on the positive terminal side connecting part.

Thus, the resistance of the positive terminal side joint is reduced owing to the silicide layer. Therefore, the effect of the invention to reduce the write current and the write voltage by making the resistance of the positive terminal side joint lower than that of the negative terminal side joint can be definitely attained. It is noted that the effect can be more remarkably exhibited when no silicide layer is formed in the negative terminal side joint.

In one aspect, the positive terminal side interconnect layer is preferably formed in a number of layers two or more, and the negative terminal side interconnect layer is preferably formed in a smaller number of layers than the positive terminal side interconnect layer.

Thus, since the interconnect layer having high heat conductivity is formed in a larger number in the positive terminal side joint than in the negative terminal side joint, the heat conductivity of the positive terminal side joint can be made higher than that of the negative terminal side joint.

Accordingly, the effect of the invention can be definitely attained.

In one aspect, the positive terminal side joint preferably further includes a heat dissipation layer formed above the positive terminal side connecting part.

Thus, the heat conductivity of the positive terminal side joint can be definitely made higher than that of the negative terminal side joint. Accordingly, the effect of the invention can be definitely attained.

Preferably, the heat dissipation layer is formed in a number of layers two or more.

Thus, the heat conductivity of the positive terminal side joint can be more conspicuously increased, and hence, the effect of the invention can be more remarkably exhibited.

In order to achieve the object, the write method of this invention for a fuse composed of a fusing part to be fused through voltage application, a positive terminal side joint connected to one end of the fusing part and a negative terminal side joint connected to the other end of the fusing part, includes a step of applying a voltage to the fuse by a write circuit including a protective resistance and a relay, and in the step of applying a voltage, a current limiting resistance is serially connected between the positive terminal side joint of the fuse and the relay and the voltage is applied to the fuse through the current limiting resistance, whereby fusing the fusing part with a current flowing to the fusing part limited within a given range. In particular, the resistances of the positive terminal side joint and the negative terminal side joint are both lowered in the fuse.

In the write method for a fuse of this invention, apart from the protective resistance used for preventing an excessive current from flowing in the write current, the current limiting resistance is serially connected between the positive terminal side joint of the fuse and the relay of the write circuit. Since the voltage is thus applied to the fuse through the current limiting resistance having appropriate resistance, an excessive current can be prevented from flowing to the fuse in fusing the fusing part and a current necessary for fusing can be allowed to flow. This will now be described in detail.

It is herein assumed that the fuse to be written has resistance R, that the fusing part of the fuse has resistance Rc and that the resistances of the positive terminal side joint and the negative terminal side joint are lowered to be approximated to 0 (zero), namely, the resistance R can be approximated to be equal to the resistance Rc. Also, it is assumed that the current limiting resistance serially connected between the positive terminal side joint of the fuse and the relay of the write circuit has resistance Rg, that a voltage Vc is applied to the positive terminal side joint of the fuse, and that the voltage is dropped by a voltage ΔVc on the positive terminal side joint of the fuse when a filament is formed. In this case, a current Ic flowing when the filament is formed is represented as follows:
Ic=Vc/Rc+ΔVc/(Rc+Rg)

The current Ic is reduced because the limiting resistance Rg is additionally provided, whereas the write voltage is increased by a voltage corresponding to Rg·Ic.

If the current limiting resistance is serially connected to the negative terminal side joint, the voltage on the negative terminal side joint is increased when the filament is formed, and hence the voltage applied between the both ends of the fuse is reduced, resulting in inhibiting the fusing part from being fused. Accordingly, the current limiting resistance is preferably connected to the positive terminal side joint.

In this manner, when a write operation is performed by applying a voltage through the current limiting resistance serially connected between the positive terminal side joint of the fuse and the relay of the write circuit, both the write voltage and the write current can be controlled. Furthermore, when the write method of this invention is employed in a PROM circuit or the like, the increase of a cell area of a driving transistor can be prevented, resulting in preventing the increase of the whole chip area.

Preferably, the current limiting resistance is disposed in the write circuit.

Also in this manner, the effect of the use of the current limiting resistance can be definitely attained.

In one aspect, the current limiting resistance is preferably disposed outside the write circuit and in the same circuit area as the fuse. Specifically, for example, when the write circuit and the fuse are disposed on different chips, the current limiting resistance is preferably disposed on the same chip as the fuse.

In this manner, the fuse can be directly connected to the current limiting resistance, and hence, generation of parasitic capacitance or the like can be prevented.

In one aspect, at least the fusing part of the fuse is preferably made of polysilicon.

Thus, the effect of the invention is attained in using a polysilicon fuse.

In one aspect, the given range of the current limited by using the current limiting resistance is preferably not less than 50 mA and not more than 100 mA.

Thus, the effect of the write method of this invention to prevent the increase of the chip area can be definitely attained.

In one aspect, the current limiting resistance preferably has resistance not less than 10 Ω and not more than 600 Ω.

Thus, the effect to reduce the write current can be remarkably exhibited.

The negative terminal side joint of the fuse is connected to an interconnect, which has interconnect resistance of, for example, approximately 2 Ω. This interconnect resistance is ignorable as compared with the resistances of the fusing part, the joint and the filament. Therefore, when the current limiting resistance has resistance approximately five or more times as high as the interconnect resistance (of, for example, approximately 10 Ω), the effect to prevent an excessive current from flowing in forming the filament can be definitely attained.

In the case where the fuse is used in a PROM circuit, it is necessary to perform the write operation with a voltage lower than the BVCES of a driving transistor. Also, there is a lower limit in the current value employed for performing the write operation for the fuse. Therefore, the maximum resistance value of the current limiting resistance corresponds to a resistance value thereof obtained when a minimum current necessary for the write operation flows to the fuse by applying a voltage equal to the BVCES. Assuming that the resistance of the filament attained in fusing the fusing part is ignorable, a value obtained by dividing the BVCES by the minimum current value necessary for the write operation is the maximum resistance value of the current limiting resistance. For example, when the BVCES is 30 V and the minimum current value necessary for the write operation is 50 mA, the maximum resistance value of the current limiting resistance is 30 V/50 mA, namely, 600 Ω.

In this manner, in the range of the resistance value of the current limiting resistance, the minimum value is a value approximately five times as high as the interconnect resistance of the interconnect connected to the negative terminal side joint, and the maximum value is determined depending upon the BVCES of the driving transistor and the minimum current value necessary for the write operation for the fuse.

In the aforementioned fuse of this invention, the positive terminal side joint and the negative terminal side joint are different from each other at least in one of its structure and its property. In particular, the positive terminal side joint has higher heat conductivity (a larger heat radiation effect) than the negative terminal side joint and has resistance equal to or lower than that of the negative terminal side joint. As a result, both the write voltage and the write current can be reduced.

Furthermore, the write current can be reduced, in the fuse in which the resistances of the both joints are reduced, by performing the write operation with the current limiting resistance serially connected between the positive terminal side joint of the fuse and the relay of the write circuit. Moreover, both the write current and the write voltage can be controlled by adjusting the resistance of the current limiting resistance.

Also, when the present invention is applied to a PROM circuit or the like, the increase of the chip area can be prevented because the write current can be reduced.

### BRIEF DESCRIPTION OF THE DRAWINGS

FIGS. 1A and 1B are diagrams of a semiconductor device including a polysilicon fuse according to Embodiment 1 of the invention, and specifically, FIG. 1A is a plan view thereof where the polysilicon fuse 100 alone is perspectively shown and FIG. 1B is a cross-sectional view taken on line Ib-Ib′ of FIG. 1A;

FIG. 2 is a diagram for showing a write method for the polysilicon fuse according to Embodiment 1 of the invention;

FIGS. 3A and 3B are diagrams of a semiconductor device including a polysilicon fuse according to Embodiment 2 of the invention, and specifically, FIG. 3A is a plan view thereof where the polysilicon fuse 200 alone is perspectively shown and FIG. 3B is a cross-sectional view taken on line IIIb-IIIb′ of FIG. 3A;

FIGS. 4A and 4B are diagrams of a semiconductor device including a polysilicon fuse according to Embodiment 3 of the invention, and specifically, FIG. 4A is a plan view thereof where the polysilicon fuse 300 alone is perspectively shown and FIG. 4B is a cross-sectional view taken on line IVb-IVb′ of FIG. 4A;

FIGS. 5A and 5B are diagrams of a semiconductor device including a polysilicon fuse according to Embodiment 4 of the invention, and specifically, FIG. 5A is a plan view thereof where the polysilicon fuse 400 alone is perspectively shown and FIG. 5B is a cross-sectional view taken on line Vb-Vb′ of FIG. 5A;

FIGS. 6A and 6B are diagrams of a semiconductor device including a polysilicon fuse according to Embodiment 5 of the invention, and specifically, FIG. 6A is a plan view thereof where the polysilicon fuse 500 alone is perspectively shown and FIG. 6B is a cross-sectional view taken on line VIb-Vlb′ of FIG. 6A;

FIGS. 7A and 7B are diagrams of a semiconductor device including a polysilicon fuse according to Embodiment 6 of the invention, and specifically, FIG. 7A is a plan view thereof where the polysilicon fuse 600 alone is perspectively shown and FIG. 7B is a cross-sectional view taken on line VIIb-VIIb′ of FIG. 7A;

FIGS. 8A and 8B are diagrams of a semiconductor device including a polysilicon fuse according to Embodiment 7 of the invention, and specifically, FIG. 8A is a plan view thereof where the polysilicon fuse 700 alone is perspectively shown and FIG. 8B is a cross-sectional view taken on line VIlIb-VIlIb′ of FIG. 8A;

FIG. 9 is a diagram for showing a write method for a polysilicon fuse according to Embodiment 8 of the invention;

FIG. 10 is a diagram for showing a write method for a polysilicon fuse according to Embodiment 9 of the invention;

FIGS. 11A and 11B are diagrams of a semiconductor device including a conventional polysilicon fuse, and specifically, FIG. 11A is a plan view thereof where the polysilicon fuse 10 alone is perspectively shown and FIG. 11B is a cross-sectional view taken on line XIb-XIb′ of FIG. 1A;

FIGS. 12A and 12B are diagrams of a semiconductor device including another conventional polysilicon fuse, and specifically, FIG. 12A is a plan view thereof where the polysilicon fuse 20 alone is perspectively shown and FIG. 12B is a cross-sectional view taken on line XIIb-XIIb′ of FIG. 12A; and

FIG. 13 is a diagram for showing a write method for a conventional polysilicon fuse.

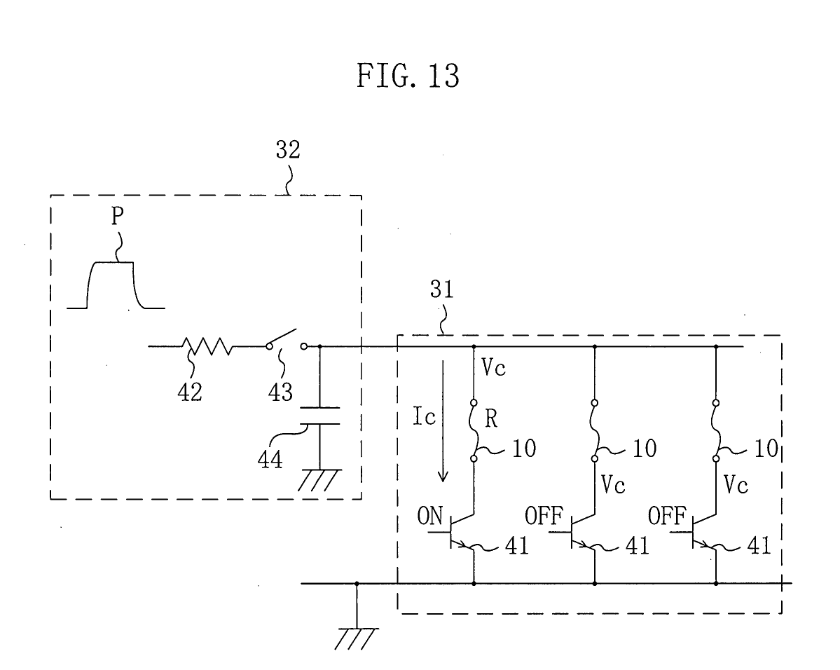

### DETAILED DESCRIPTION OF THE INVENTION

Preferred embodiments of the invention will now be described with reference to the accompanying drawings.

### Embodiment 1

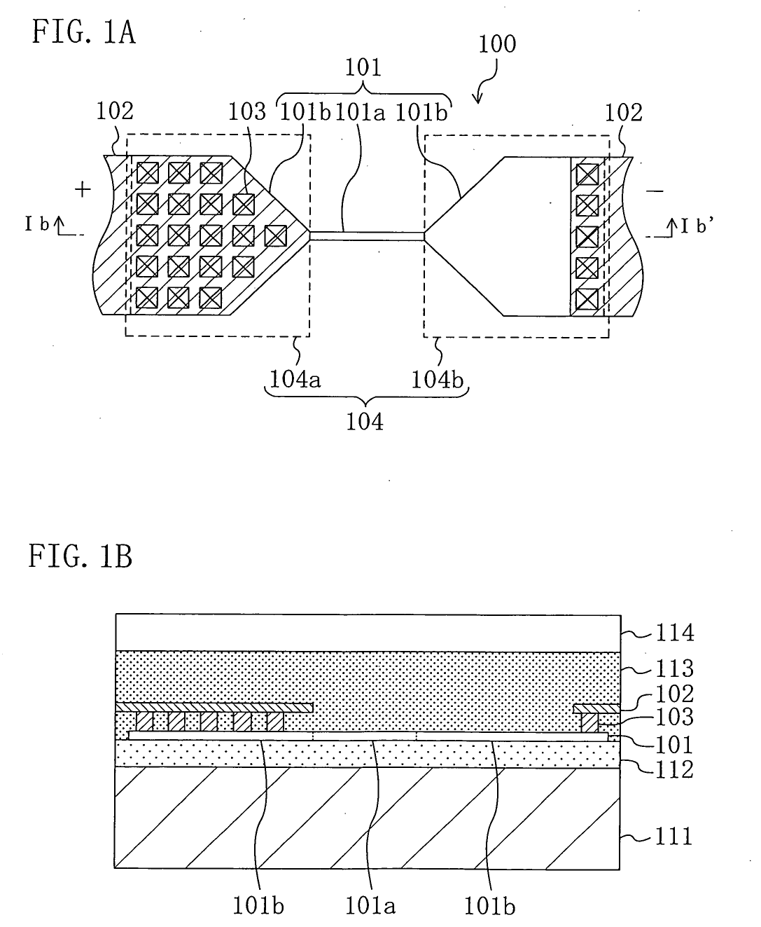

FIGS. 1A and 1B are diagrams of a semiconductor device including a polysilicon fuse according to Embodiment 1, and specifically, FIG. 1A is a plan view thereof where the polysilicon fuse 100 alone is perspectively shown and FIG. 1B is a cross-sectional view taken on line Ib-lb′ of FIG. 1A.

As shown in FIG. 1A, the polysilicon fuse 100 includes a fuse layer 101, an interconnect layer 102 and contacts 103 for electrically connecting the fuse layer 101 and the interconnect layer 102 to each other.

The fuse layer 101 is composed of a fusing part 101a to be fused through voltage application and a connecting part 101b connected to each end of the fusing part 101a, and at least a portion of each connecting part 101b disposed on the other side of the fusing part 101a is used as an interconnect region (not shown) to be connected to the interconnect layer 102.

Also, an interconnect (not shown) is connected to the polysilicon fuse 100 for voltage application or the like.

The connecting parts 101b, the interconnect layer 102 disposed above the connecting part 101b and the contacts 103 together form joints 104. One of the joints 104 to which a voltage is applied through the interconnect to attain a high voltage in fusing is designated as a positive terminal side joint 104a and the other joint 104 that attains a low voltage in fusing is designated as a negative terminal side joint 104b.

Furthermore, the connecting part 101b has a width, for example, four or more times as large as the fusing part 101a. Therefore, when a voltage is applied to the polysilicon fuse 100, the fusing part 110a where a current density is high is fused.

Next, as shown in the cross-sectional view of FIG. 1B, the semiconductor device including the polysilicon fuse 100 includes a substrate 111, a thermal oxidation film 112 formed on the substrate 111, the fuse layer 101 formed on the thermal oxidation film 112, the interconnect layer 102 for applying a voltage to the fuse layer 101 and the contacts 103 for connecting the fuse layer 101 and the interconnect layer 102 to each other. Also, an interlayer insulating film 113 is formed above the thermal oxidation film 112 for covering the fuse layer 101, the interconnect layer 102 and the contacts 103, and a passivation film 114 is formed on the interlayer insulating film 113.

In the polysilicon fuse of this embodiment, the interconnect layer 102 is formed over the connecting part 101b in the positive terminal side joint 104a but the interconnect layer 102 is formed above a part of the connecting part 101b in the negative terminal side joint 104b. Also, the contacts 103 for connecting the connecting part 101b and the interconnect layer 102 are formed in a larger number in the positive terminal side joint 104a than in the negative terminal side joint 104b, whereas all the contacts 103 have the same area.

In this manner, the electric resistance of the positive terminal side joint 104a is lowered. Also, the interconnect layer 102 and the contacts 103 are made of a material having higher heat conductivity than the interlayer insulating film 113, and the positive terminal side joint 104a has higher heat conductivity than the negative terminal side joint 104b.

The interlayer insulating film 113 is made of, for example, SiO₂, and the passivation film 114 is made of, for example, SiN, which does not limit the invention. Also, another kind of insulating film may be used instead of the thermal oxidation film 112.

Now, a write method for the polysilicon fuse of this embodiment described above will be described with reference to the accompanying drawing.

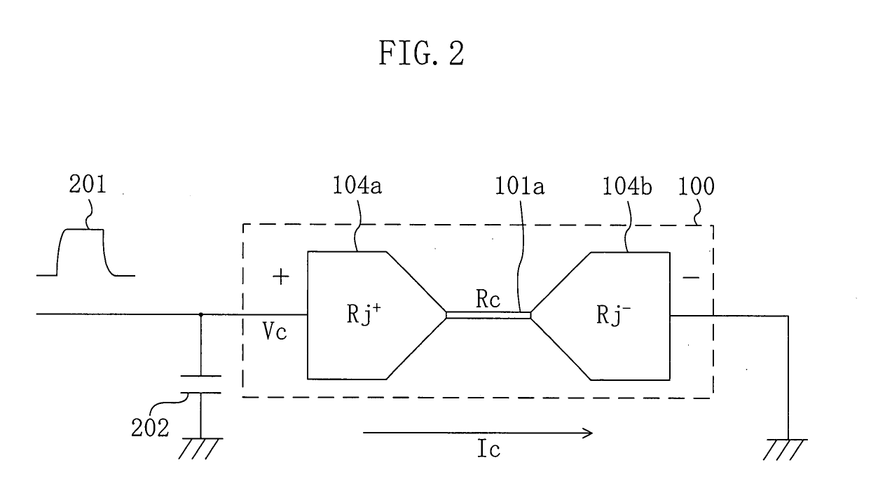

FIG. 2 shows a write operation performed by applying a voltage pulse 201 to the polysilicon fuse 100.

Although the detailed structure shown in FIG. 1A is omitted in FIG. 2, the polysilicon fuse 100 is composed of the positive terminal side joint 104a having resistance Rj⁺, the fusing part 101a having resistance Rc and the negative terminal side joint 104b having resistance Rj⁻. Also, the positive terminal side joint of the polysilicon fuse 100 is connected to the interconnect for applying the voltage pulse 201 and the negative terminal side joint is grounded.

At this point, in the case where the polysilicon fuse 100 is used in, for example, a PROM circuit or the like, the PROM circuit or the like includes a driving transistor or the like (not shown) for applying a write current.

Also, a write circuit and a relay or the like (not shown) for supplying the voltage pulse have given stray capacitance, which is shown as stray capacitance 202 in FIG. 2. In general, the stray capacitance 202 has capacity of approximately 1 through 10 pF, and it is very difficult to make it 0 (zero).

In fusing the polysilicon fuse, the voltage pulse 201 having a given rise time constant, a given voltage value, a given pulse time and the like is applied to the polysilicon fuse 100. At this point, assuming that the positive terminal side of the polysilicon fuse 100 has a voltage Vc and that a current Ic flows to the polysilicon fuse 100, the current Ic is increased as the voltage Vc increases, and the internal temperature of the fusing part 101a is increased owing to Joule heat.

As described above, the positive terminal side joint 104a of the polysilicon fuse 100 of this embodiment has high heat conductivity. Therefore, even when the length of the fusing part 101a is reduced for lowering the write voltage, the peak of the temperature distribution in the fusing part 101a is not shifted toward the positive terminal side joint but is positioned in the vicinity of the center. Therefore, when the fusing part 101a is fused as a result of the increase of the temperature, the connecting part 101b can be prevented from melting in the positive terminal side joint 104a. As a result, the increase of the write current can be prevented.

The process for fusing the polysilicon fuse 100 will now be described in detail.

The resistance Rj⁺ of the positive terminal side joint 104a of the polysilicon fuse 100 of this embodiment is lowered to several Ω, which is sufficiently smaller than that of the negative terminal side joint 104b, and hence can be approximated to 0 (zero).

Thus, the current Ic flowing to the polysilicon fuse 100 is represented as follows:
Ic=Vc/(Rc+Rj⁻)

When the temperature of the peak of the temperature distribution positioned in the vicinity of the center of the fusing part 101a as described above reaches 1410° C., that is, the melting point of Si, polysilicon included in the fusing part 101a is partly melted, and a filament made of the melted polysilicon is formed in the fusing part 101a. The resistance of the filament is approximately several tens Ω, which is much smaller than the resistance of the fusing part 101a, and therefore, the resistance R of the polysilicon fuse 100 is abruptly lowered. Accordingly, the voltage Vc is also temporarily lowered, and the stray capacitance 202 discharges. Assuming that the voltage Vc is dropped by a voltage ΔVc, the voltage ΔVc is larger as the resistance R of the polysilicon fuse 100 is more largely lowered. For example, in the case where the sheet resistance of polysilicon is 200 Ω/□ and the fusing part 101a has a width of 0.8 μm, the dropped voltage ΔVc is approximately 2V.

As a result, not only a current derived from the voltage pulse 201 but also a discharge current ΔIc(=ΔVc/R=ΔVc/(Rc+Rj⁻)) is applied to the polysilicon fuse 100. In other words, when the filament is formed, the current flowing to the polysilicon fuse 100 is abruptly increased, as compared with that flowing before the formation of the filament, to a current corresponding to Vc/(Rc+Rj⁻)+ΔVc/(Rc+Rj⁻). For example, in the case where the sheet resistance of polysilicon is 200 Ω/□ and the fusing part 101a has a width of 0.8 μm, the current is approximately 50 mA.

Furthermore, the thus formed filament grows in both the width direction and the thickness direction of the fusing part 101a and is ultimately fissioned and fused owing to the surface tension of the filament itself and the effect of film stress.

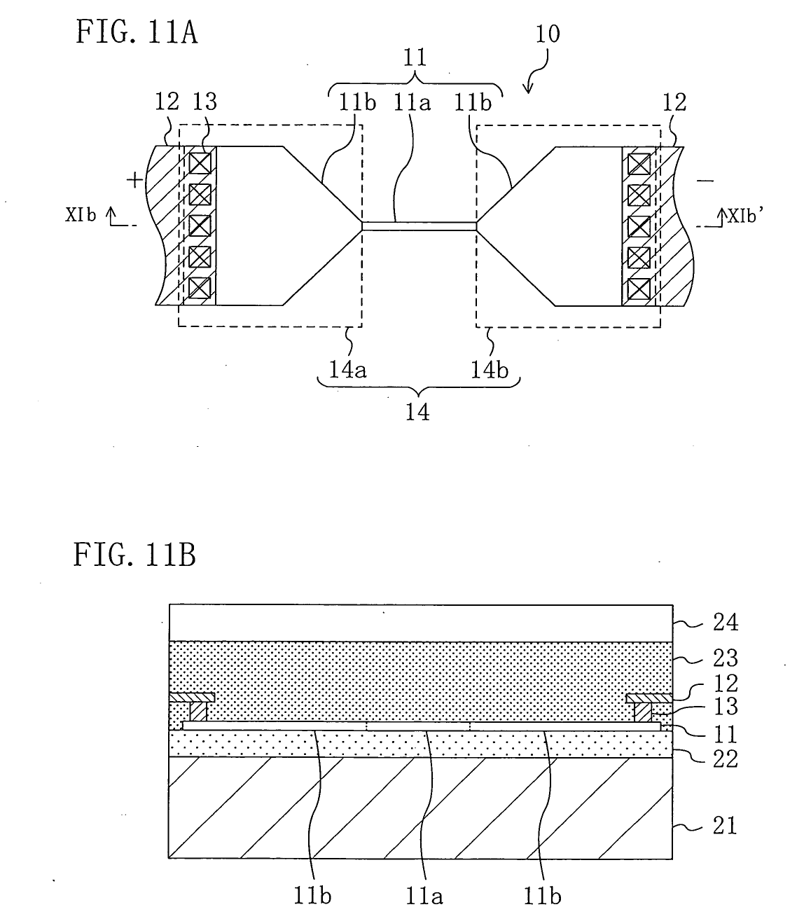

At this point, since the resistance Rj⁺ of the positive terminal side joint 104a is lowered to be approximated to 0, the write voltage can be lowered by a voltage corresponding to Rj⁺·Ic than in the conventional polysilicon fuse shown in FIGS. 11A and 11B.

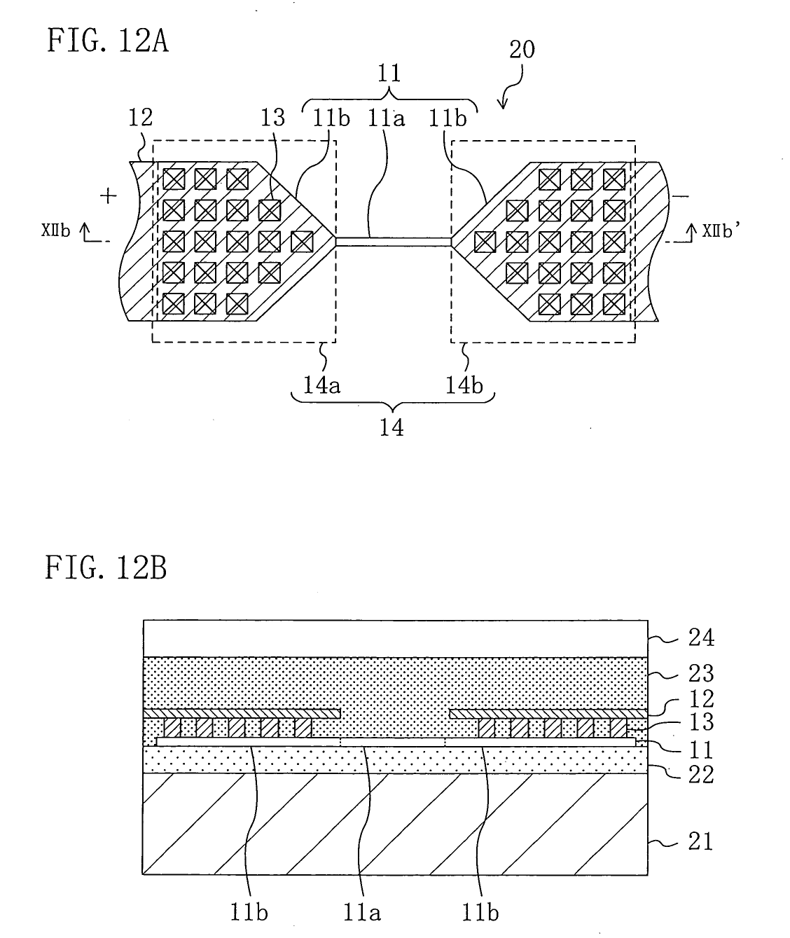

Also, the resistance of the negative terminal side joint 104b is not lowered but remains to be Rj⁻. Therefore, as compared with the conventional polysilicon fuse (of FIGS. 12A and 12B) in which the resistances of both the positive terminal side joint and the negative terminal side joint are lowered, the write current flowing in forming the filament is reduced by the resistance Rj⁻.

For example, in the conventional polysilicon fuse shown in FIGS. 12A and 12B, in the case where the sheet resistance of polysilicon is 200 Ω/□ and the fusing part 11a has a width of 0.8 μm, the write current is approximately 120 mA. On the contrary, in the polysilicon fuse 100 of this embodiment, in the similar case where the sheet resistance of polysilicon is 200 Ω/□ and the fusing part 101a has a width of 0.8 μm, the write current is approximately 50 mA.

In this manner, in the polysilicon fuse 100 of this embodiment, since the heat conductivity and the resistance are different between the positive terminal side joint 104a and the negative terminal side joint 104b, both the write voltage and the write current can be reduced.

Also, in the case where the polysilicon fuse 100 is used in a PROM circuit or the like, since the write current for the polysilicon fuse 100 is reduced, the cell area of the driving transistor can be reduced, resulting in reducing the chip area of the whole semiconductor chip.

In this embodiment, all the contacts 103 have the same area and are formed in a larger number in the positive terminal side joint 104a than in the negative terminal side joint 104b. However, the effect of this embodiment can be realized as far as the total area of the contacts 103 formed in the positive terminal side joint 104a is larger than the total area of the contacts 103 formed in the negative terminal side joint 104b. For example, a single contact 103 may be formed in each of the positive terminal side joint 104a and the negative terminal side joint 104b with the area of the contact 103 formed in the positive terminal side joint 104a set to be larger than that formed in the negative terminal side joint 104b.

### Embodiment 2

A polysilicon fuse according to Embodiment 2 of the invention will now be described.

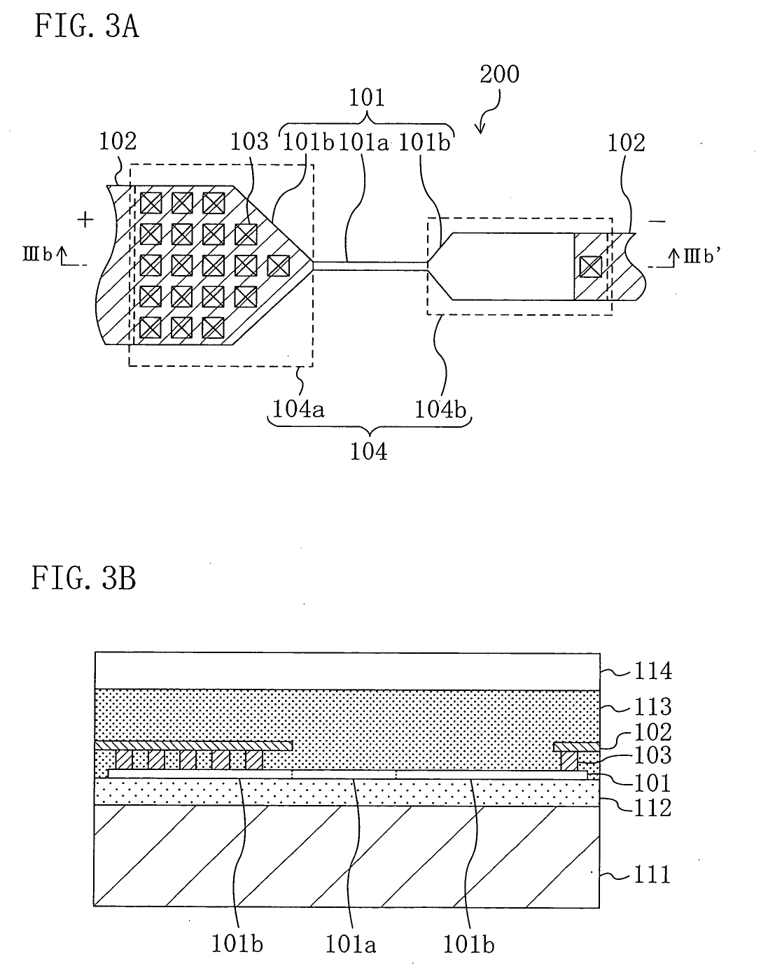

FIGS. 3A and 3B are diagrams of a semiconductor device including a polysilicon fuse according to Embodiment 2, and specifically, FIG. 3A is a plan view thereof where the polysilicon fuse 200 alone is perspectively shown and FIG. 3B is a cross-sectional view taken on line IIIb-IIIb′ of FIG. 3A.

In FIGS. 3A and 3B, like reference numerals are used to refer to like elements used in Embodiment 1 shown in FIGS. 1A and 1B and the detailed description is herein omitted.

The polysilicon fuse 200 of this embodiment is different from that of Embodiment 1 in the width of the negative terminal side joint 104b being smaller than that of the positive terminal side joint 104a, whereas the “width” herein means a width of the positive terminal side joint 104a or the negative terminal side joint 104b excluding its tapered portion in the vicinity of the fusing part 101a.

Since the resistance is higher as the cross-section is smaller, the resistance of the negative terminal side joint 104b of this embodiment is higher than in Embodiment 1.

Also, since the heat radiation effect is larger as the area is larger, the heat radiation effect of the negative terminal side joint 104b of this embodiment is lower than in Embodiment 1.

As a result, the effect for reducing both the write voltage and the write current described in Embodiment 1 can be more definitely realized in Embodiment 2.

It is noted that the interconnect layer 102 is formed over the connecting part 101b in the positive terminal side joint 104a of this embodiment. However, also in the case where the interconnect layer 102 is formed above merely a part of the connecting part 101b, the effect to increase the resistance of the negative terminal side joint 104b by reducing the width thereof can be attained.

### Embodiment 3

A polysilicon fuse according to Embodiment 3 of the invention will now be described.

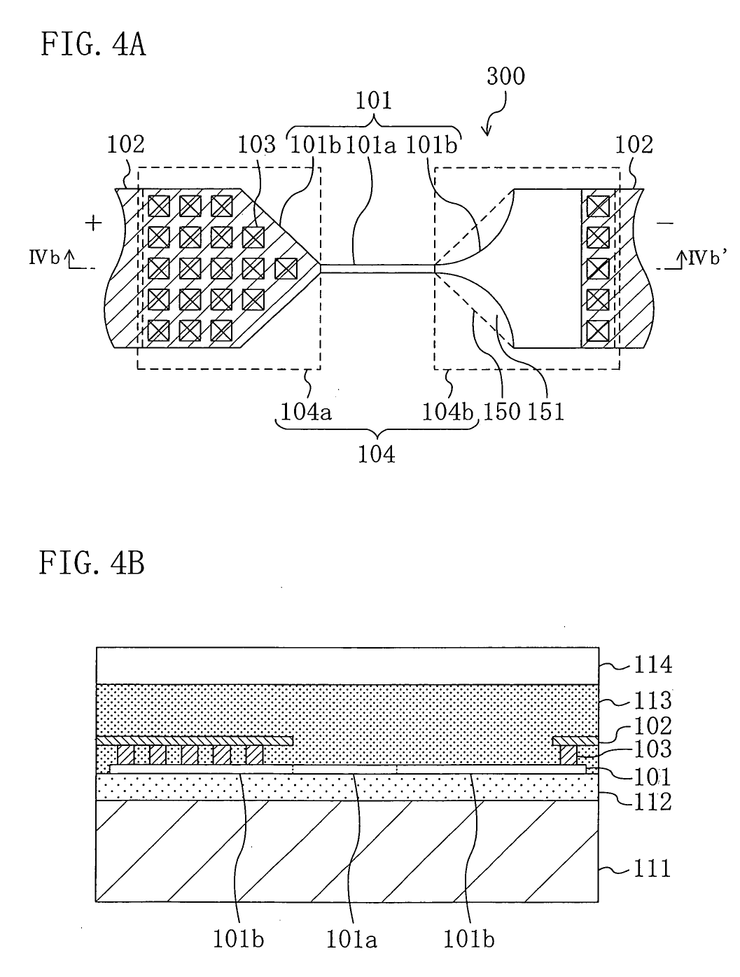

FIGS. 4A and 4B are diagrams of a semiconductor device including a polysilicon fuse according to Embodiment 3, and specifically, FIG. 4A is a plan view thereof where the polysilicon fuse 300 alone is perspectively shown and FIG. 4B is a cross-sectional view taken on line IVb-IVb′ of FIG. 4A.

In FIGS. 4A and 4B, like reference numerals are used to refer to like elements used in Embodiment 1 shown in FIGS. 1A and 1B and the detailed description is herein omitted.

The polysilicon fuse 300 of this embodiment is different from that of Embodiment 1 in the negative terminal side joint 104b being narrower than the positive terminal side joint 104a in the vicinity of the fusing part 101a. This will now be specifically described.

The positive terminal side joint 104a is in a taper shape that is linearly tapered toward the fusing part 101a from a position away by a given distance from the portion thereof connected to the fusing part 101a. On the contrary, the negative terminal side joint 104b is similarly tapered toward the fusing part 101a from a position away by a given distance from the portion thereof connected to the fusing part 101a, but is not linearly tapered but in a shape, for example, obtained by dropping arc-shaped areas 151 out of a taper shape 105 similar to the taper shape of the positive terminal side joint.

Alternatively, the negative terminal side joint 104b may be in a shape tapered toward the fusing part 101a from a position away by a larger distance than in the positive terminal side joint 104a from the fusing part 101a.

In this manner, the negative terminal side joint 104b is narrower than the positive terminal side joint 104a at least in the vicinity of the fusing part 101a.

Thus, the negative terminal side joint 104b attains high resistance and a small-heat radiation effect at least in the vicinity of the fusing part 111a as in Embodiment 2, and therefore, the effect of the invention can be definitely realized.

### Embodiment 4

A polysilicon fuse according to Embodiment 4 of the invention will now be described.

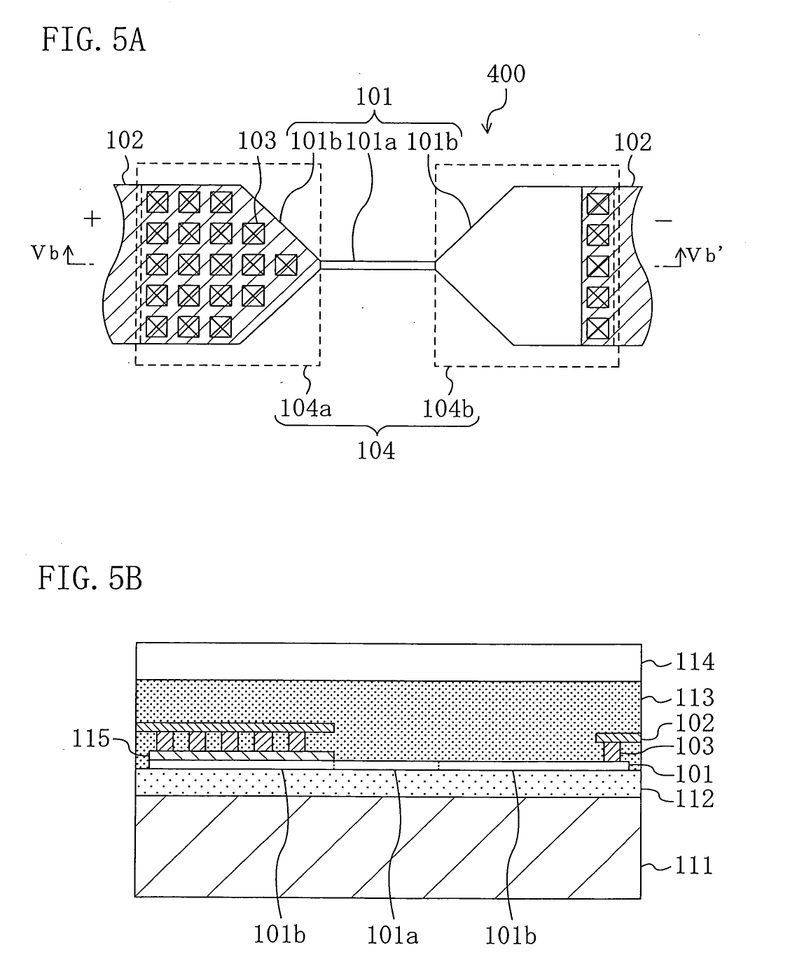

FIGS. 5A and 5B are diagrams of a semiconductor device including a polysilicon fuse according to Embodiment 4, and specifically, FIG. 5A is a plan view thereof where the polysilicon fuse 400 alone is perspectively shown and FIG. 5B is a cross-sectional view taken on line Vb-Vb′ of FIG. 5A.

In FIGS. 5A and 5B, like reference numerals are used to refer to like elements used in Embodiment 1 shown in FIGS. 1A and 1B and the detailed description is herein omitted.

The polysilicon fuse 400 of this embodiment is different from that of Embodiment 1 in a silicide layer 115 formed on the fuse layer 101 in the positive terminal side joint 104a (namely, on the contacting part 101b in the positive terminal side joint). Therefore, the contacts 103 connect the interconnect layer 102 and the silicide layer 115 to each other.

Thus, since the silicide layer 115 has lower resistance than the fuse layer 101 made of polysilicon (i.e., since the resistivity of the silicide layer 115 is lower than that of the fuse layer 101 made of polysilicon), the resistance of the positive terminal side joint 104a can be more largely reduced than in Embodiment 1.

As a result, the effect of the invention attained by reducing the resistance of the positive terminal side joint 104a can be more remarkably realized.

### Embodiment 5

A polysilicon fuse according to Embodiment 5 of the invention will now be described.

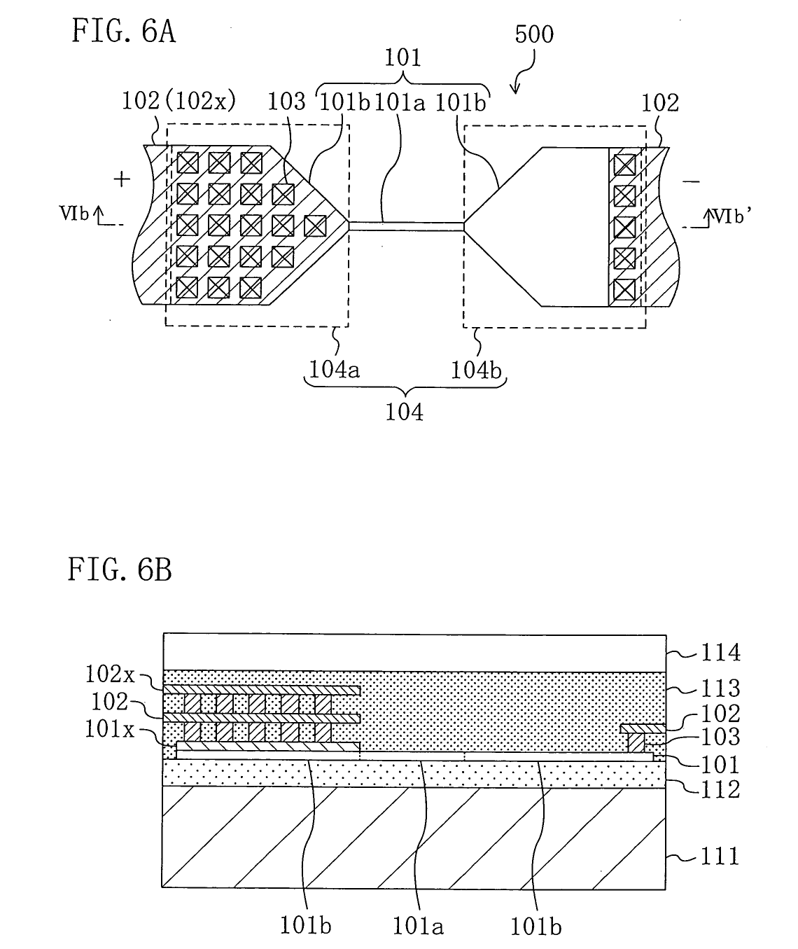

FIGS. 6A and 6B are diagrams of a semiconductor device including a polysilicon fuse according to Embodiment 5, and specifically, FIG. 6A is a plan view thereof where the polysilicon fuse 500 alone is perspectively shown and FIG. 6B is a cross-sectional view taken on line VIb-VIb′ of FIG. 6A.

In FIGS. 6A and 6B, like reference numerals are used to refer to like elements used in Embodiment 1 shown in FIGS. 1A and 1B and the detailed description is herein omitted.

The polysilicon fuse 500 of this embodiment is different from that of Embodiment 1 in an additional fuse layer 101x formed on the fuse layer 101 and an additional interconnect layer 102x formed above the interconnect layer 102 in the positive terminal side joint 104a. In this case, the contacts 103 connect the additional fuse layer 101x and the interconnect layer 102 to each other and the interconnect layer 102 and the additional interconnect layer 102x to each other.

Thus, the positive terminal side joint 104a can attain further lower resistance and further higher heat conductivity. Therefore, the effect of the invention can be more remarkably realized.

### Embodiment 6

A polysilicon fuse according to Embodiment 6 of the invention will now be described.

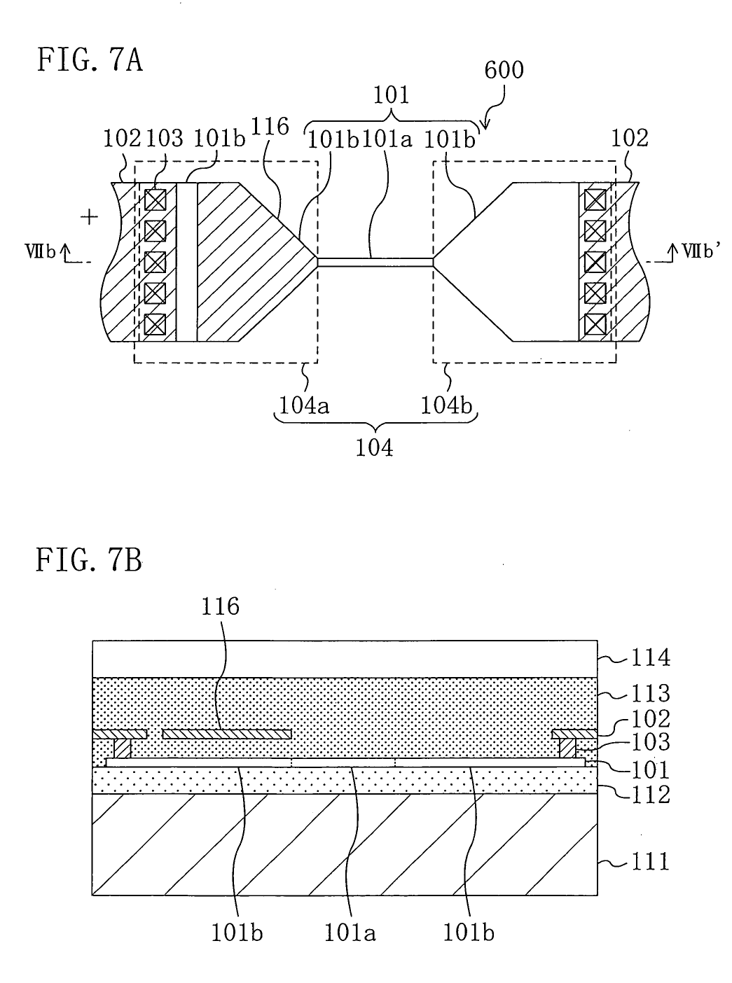

FIGS. 7A and 7B are diagrams of a semiconductor device including a polysilicon fuse according to Embodiment 6, and specifically, FIG. 7A is a plan view thereof where the polysilicon fuse 600 alone is perspectively shown and FIG. 7B is a cross-sectional view taken on line VIIb-VIIb′ of FIG. 7A.

In FIGS. 7A and 7B, like reference numerals are used to refer to like elements used in Embodiment 1 shown in FIGS. 1A and 1B and the detailed description is herein omitted.

In the polysilicon fuse 100 of Embodiment 1 shown in FIGS. 1A and 1B, the interconnect layer 102 is formed over the connecting part 101b in the positive terminal side joint 104a and above a part of the connecting part 101b in the negative terminal side joint 104b (namely, on the interconnect region on the other side of the fusing part 101a although not specifically shown in the drawings).

In contrast, in the polysilicon fuse 600 of this embodiment, the interconnect layer 102 is formed above merely a part of the connecting part 101b in both the positive terminal side joint 104a and the negative terminal side joint 104b.

Also, in the positive terminal side joint 104a, a heat dissipation layer 116 is formed above the fuse layer 101 with the interlayer insulating film 113 sandwiched therebetween. In this case, the heat dissipation layer 116 is made of a material with higher heat conductivity than the interlayer insulating film 113. Also, the heat dissipation layer 116 is electrically connected neither to the interconnect layer 102 nor to the fuse layer 101.

Owing to this structure, the resistance of the positive terminal side joint 104a is equal to the resistance of the negative terminal side joint 104b in the polysilicon fuse 600 of this embodiment. Furthermore, the positive terminal side joint 104a has higher heat conductivity than the negative terminal side joint 104b.

The polysilicon fuse 600 of this embodiment is fused through the same process as in Embodiment 1.

It is herein assumed that the method described with reference to FIG. 2 is employed for fusing the polysilicon fuse 600 of this embodiment instead of the polysilicon fuse 100 of Embodiment 1.

Differently from Embodiment 1, the resistance of the positive terminal side joint 104a of the polysilicon fuse 600 of this embodiment is not reduced. Therefore, the resistance Rj⁺ of the positive terminal side joint 104a cannot be approximated to 0 and has the same value as the resistance Rj⁻.

Accordingly, Rj⁺=Rj⁻=Rj, and each current has a value obtained by substituting 2Rj for Rj⁻ of Embodiment 1.

Specifically, assuming that the positive terminal of the fuse has a voltage Vc, the current flowing through the polysilicon fuse 600 has a value corresponding to Vc/(Rc+2Rj), the discharge current discharged from the stray capacitance 202 in forming the filament has a value corresponding to ΔVc/(Rc+2Rj), and the current flowing to the fusing part 101a in forming the filament has a value corresponding to Vc/(Rc+2Rj)+ΔVc/(Rc+2Rj).

Furthermore, since the heat dissipation layer 116 is used in this embodiment, the heat conductivity of the positive terminal side joint 104a is higher than that of the negative terminal side joint 104b.

Therefore, in the polysilicon fuse 600 of this embodiment, the peak of the temperature distribution in the fusing part 101a obtained in fusing is not shifted toward the positive terminal side joint but is positioned in the vicinity of the center in the same manner as in Embodiment 1. Accordingly, the connecting part 101b can be prevented from melting also in this embodiment, and therefore, the increase of the write current can be prevented even when the length of the fusing part 101a is reduced for lowering the write voltage.

### Embodiment 7

A polysilicon fuse according to Embodiment 7 of the invention will now be described.

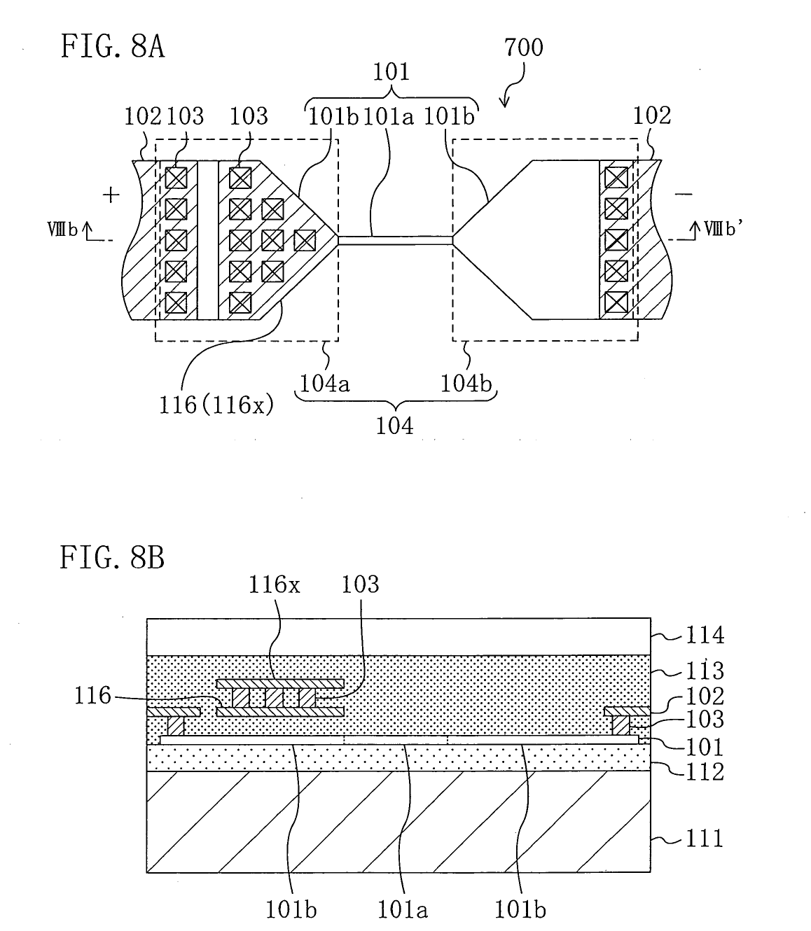

FIGS. 8A and 8B are diagrams of a semiconductor device including a polysilicon fuse according to Embodiment 7, and specifically, FIG. 8A is a plan view thereof where the polysilicon fuse 700 alone is perspectively shown and FIG. 8B is a cross-sectional view taken on line VIIIb-VIIIb′ of FIG. 8A.

In FIGS. 8A and 8B, like reference numerals are used to refer to like elements used in Embodiment 6 shown in FIGS. 7A and 7B and the detailed description is herein omitted.

The polysilicon fuse 700 of this embodiment is different from that of Embodiment 6 in a heat dissipation layer having a two-layered structure composed of the heat dissipation layer 116 and an additional heat dissipation layer 116x formed thereon and the heat dissipation layer 116 and the heat dissipation layer 116 being connected through the contacts 103.

Owing to this structure, the heat conductivity of the positive terminal side joint 104a is further higher than in Embodiment 6, and hence, the effect to reduce the write current can be more remarkably exhibited.

Although the heat dissipation layer of this embodiment has a two-layered structure, three or more heat dissipation layers connected to one another through the contacts may be employed instead. Also, as far as the number of heat dissipation layers formed in the positive terminal side joint 104a is larger, a heat dissipation layer may be formed also in the negative terminal side joint 104b.

In each of Embodiments 1 through 7, the fuse layer 101 is made of polysilicon and the fuse is a polysilicon fuse. However, even when the fuse layer 101 is made of silicide or the like, the effect of this invention can be realized, and application to another kind of fuse is not excluded from the scope of the invention.

Furthermore, it goes without saying that the structures described in Embodiments 1 through 7 can be optionally combined with each other. For example, a structure in which the width of the negative terminal side joint 104b is reduced as in Embodiment 2 and the silicide layer 115 is formed in the positive terminal side joint 104a as in Embodiment 4 can be employed.

### Embodiment 8

A write method for a polysilicon fuse according to Embodiment 8 of the invention will now be described.

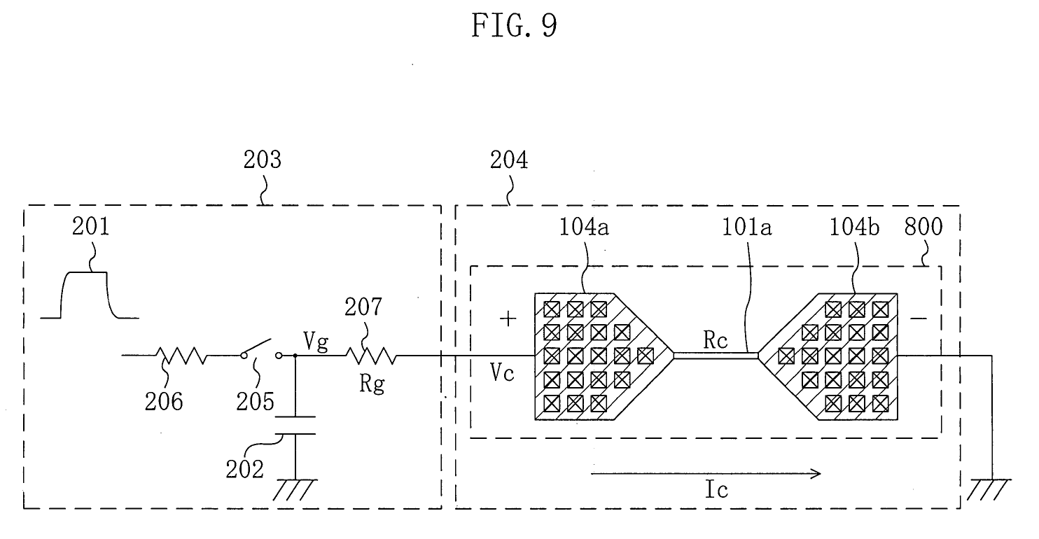

FIG. 9 is a diagram for explaining a write method for a polysilicon fuse 800 mounted on a semiconductor chip 204 by using a write circuit 203.

In this embodiment, the polysilicon fuse 800 is composed of a positive terminal side joint 104a, a fusing part 101a and a negative terminal side joint 104b. Although not described in detail, the resistances of the positive terminal side joint 104a and the negative terminal side joint 104b are both reduced to have a value ignorable as compared with that of the fusing part 101a. This polysilicon fuse may be, for example, the polysilicon fuse of Conventional Example 2 shown in FIGS. 12A and 12B in which the interconnect layer is formed over the connecting part and the interconnect layer and the connecting part are connected to each other through the contacts.

Also, the write circuit 203 includes a relay 205 and a protective resistance 206 for changing the voltage on the positive terminal side of the fuse in accordance with the change of a write current, and also includes a stray capacitance 203 accompanying the relay 205 and the like. In addition, the write circuit 203 includes a current limiting resistance 207 having a given resistance value for limiting a current flowing to the polysilicon fuse 800. The current limiting resistance 207 is connected between the relay 205 and the positive terminal side joint.

The stray capacitance 203 has capacity of, for example, approximately 1 through 10 pF, and it is very difficult to make it 0 (zero).

The write method for the polysilicon fuse 800 of this embodiment using the aforementioned circuit configuration is performed in the same manner as in the conventional write method for a polysilicon fuse including joints with lowered resistance in the following point:

When a voltage pulse is applied, the temperature is increased in the fusing part 110a due to Joule heat and reaches 1410° C., that is, the melting point of Si. At this point, polysilicon included in the fusing part 110a is partly melted, and a filament made of the melted polysilicon is formed in the fusing part 111a. Since the filament has much lower resistance than the fusing part 101a not melted, the resistance of the polysilicon fuse 800 is rapidly lowered. Accordingly, the stray capacitance 203 discharges, and a discharge current thus caused also flows to the polysilicon fuse 800. The filament grows in both the width direction and the thickness direction of the fusing part 101a and is ultimately fissioned and fused owing to the surface tension of the filament itself and the effect of film stress.

Such fusing process is the same as that of the conventional write method.

In this embodiment, however, the current limiting resistance 207 is serially connected to the positive terminal side joint of the polysilicon fuse 800, and hence, the voltage pulse 201 is applied to the polysilicon fuse 800 through the current limiting resistance 207. Therefore, the write current can be adjusted within a given range. This effect will now be specifically described.

In the polysilicon fuse 800 of this embodiment, the resistances of both the positive terminal side joint 104a and the negative terminal side joint 104b are reduced to be approximated to 0, and therefore, the resistance R of the polysilicon fuse 800 can be approximated to be equal to the resistance Rc of the fusing part 101a.

Also, it is assumed that the current limiting resistance 207 has resistance Rg and that the positive terminal of the current limiting resistance 207 has a voltage Vg.

Accordingly, when the positive terminal of the polysilicon fuse 800 has a voltage Vc, the current Ic flowing to the polysilicon fuse 800 is represented as Vc/Rc.

Furthermore, when the filament having low resistance is formed in the fusing part 101a, the resistance Rc of the polysilicon fuse 800 is temporarily lowered and hence the voltage Vc is also temporarily dropped. As a result, the voltage Vg is also dropped, and the stray capacitance 203 discharges. Assuming that the voltage Vg is dropped by a voltage ΔVg, the discharge current discharged from the stray capacitance 203 has a current value corresponding to ΔVg/(Rg+Rc), and this discharge current is applied to the polysilicon fuse 800.

In other words, not only the current Vc/Rc derived from the general voltage pulse 201 but also the discharge current ΔVg/(Rg+Rc) is applied to the polysilicon fuse 800. Eventually, a current corresponding to (Vc/Rc)+ΔVg/(Rg+Rc) flows to the polysilicon fuse 800 and the current is abruptly increased when the filament is formed. The fusing part 110a is fused by this current, and thus, a write operation is performed.

As described above, according to Embodiment 8, the write operation is performed with the current limiting resistance 207 serially connected to the positive terminal side joint of the polysilicon fuse 800. Therefore, although the write voltage is increased by a voltage corresponding to the dropped voltage Ic·Rg in the current limiting resistance 207, the transient current flowing to the filament is reduced, and hence, the write current is reduced. Furthermore, both the write current and the write voltage can be controlled by appropriately selecting the resistance Rg of the current limiting resistance 207.

In the case where the current limiting resistance 207 is serially connected to the negative terminal side joint of the polysilicon fuse 800, it is difficult to fuse the polysilicon fuse 800. This is probably for the following reason: When the transient current flows to the polysilicon fuse 800 in forming the filament, the voltage on the negative terminal of the polysilicon fuse 800 is increased in a short period of time. As a result, the voltage applied between the positive terminal and the negative terminal of the polysilicon fuse 800 is lowered, which prevents the polysilicon fuse 800 from fusing.

For the same reason, an interconnect or the like connected to the negative terminal side joint of the polysilicon fuse 800 for grounding it is set to have resistance as low as possible. For example, this resistance is preferably several Ωor less.

As described above, when the current limiting resistance 207 with given resistance is connected to the positive terminal side joint of the polysilicon fuse 800 and the voltage pulse 201 is applied through the current limiting resistance 207 to the polysilicon fuse 800 for fusing, both the write voltage and the write current can be controlled. Furthermore, when this write method of this embodiment is used in a PROM circuit or the like, the increase of the cell area of a driving transistor can be prevented, and hence, the increase of the whole chip area can be prevented.

Specifically, it is assumed in this embodiment that the sheet resistance of the polysilicon is 200 Ω/□, that the fusing part 101a has a width of 0.8 μm, that the voltage of the voltage pulse 201 is 12 V and that the resistance of the protective resistance 206 is 51 Ω. In this case, when the resistance Rg of the current limiting resistance 207 is set to, for example, 100 Ω, the current flowing in forming the filament can be limited to, for example, 75 mA. Thus, an excessive current can be prevented from flowing.

For comparison, the polysilicon fuse is fused without using the current limiting resistance. In this case, the current flowing in forming the filament is, for example, approximately 120 mA.

Also, the interconnect resistance of the interconnect connected to the negative terminal side joint 104b of the polysilicon fuse 800 is, for example, approximately 2 through 3 Ω. Therefore, when the resistance of the current limiting resistance 207 is five or more times as high as this interconnect resistance, namely, for example, is approximately 10 Ωor more, the effect of this invention to limit the write current can be definitely realized. In this manner, the lower limit of the resistance of the current limiting resistance 207 for realizing the effect of the invention is determined.

Furthermore, the upper limit of the resistance value of the current limiting resistance 207 is determined for performing the write operation with a voltage lower than the BVCES (of, for example, approximately 30V) of the driving transistor used in the PROM circuit or the like. Specifically, when it is assumed that a minimum current necessary for fusing the fusing part 101a is approximately 50 mA and that the resistance of the filament, that is, several tens Ω, is ignorable, the upper limit is 30 mV/50 mA, namely, 600 Ω. The minimum current necessary for fusing the fusing part 101a and the BVCES are different depending upon the configurations of the circuit and the fuse, and the upper limit of the resistance value of the current limiting resistance 207 is obtained on the basis of these values.

Although the write method of this embodiment is described by exemplifying the case where the conventional fuse including the positive terminal side joint and the negative terminal side joint having the same structure and the same property is used, this write method is applicable to, for example, a fuse in which the positive terminal side joint has higher heat conductivity than the negative terminal side joint.

### Embodiment 9

A write method for a polysilicon fuse according to Embodiment 9 of the invention will now be described.

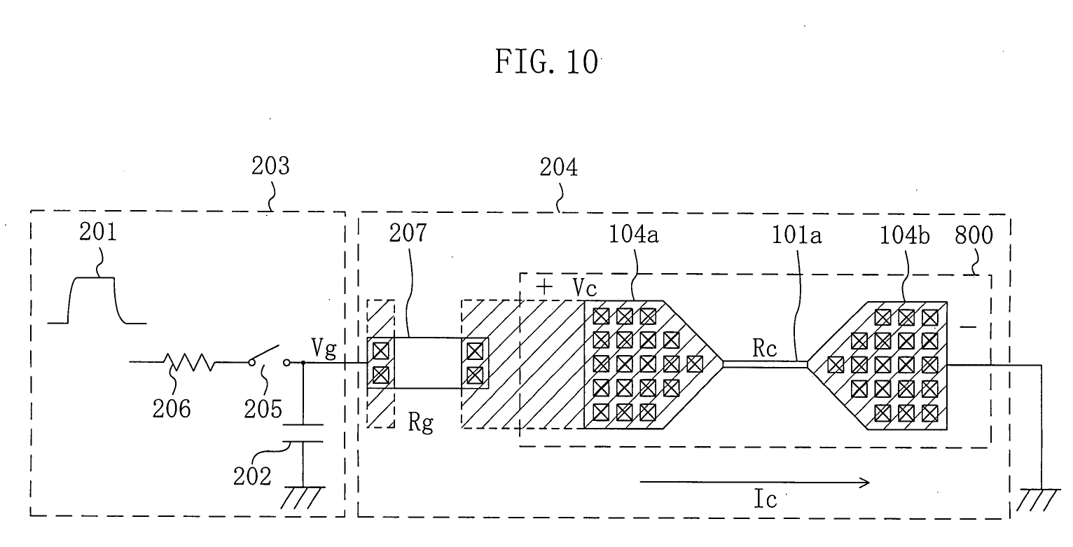

FIG. 10 is a diagram for showing the write method for a fuse of this embodiment. The current limiting resistance 207, which is included in the write circuit 203 in Embodiment 8, is provided in the same circuit area as the polysilicon fuse 800 in this embodiment, and specifically is provided on the side of the positive terminal side joint 104a of the semiconductor chip 204 in FIG. 10. Apart from this difference, the write method of this embodiment is the same as that shown in FIG. 9 and hence the detailed description is omitted by using, in FIG. 10, the same reference numerals as those shown in FIG. 9.

Also in this manner, the same effect as that of Embodiment 8 can be attained. Furthermore, since the current limiting resistance 207 is provided in the semiconductor chip 204, the polysilicon fuse 800 and the current limiting resistance 207 can be directly connected to each other. Therefore, the polysilicon fuse can be more stably fused without being affected by parasitic capacitance or the like.

As described so far, a write voltage and a write current for a fuse can be reduced according to the invention, and hence the chip size can be reduced. Accordingly, the invention is useful for a semiconductor device or the like including a writable PROM circuit and the like.

1. A fuse comprising:
a fusing part to be fused through voltage application;
a positive terminal side joint connected to one end of said fusing part; and
a negative terminal side joint connected to the other end of said fusing part,
wherein said positive terminal side joint and said negative terminal side joint are different from each other in at least one of a structure and a property.

2. The fuse of claim 1,
wherein said positive terminal side joint has higher heat conductivity than said negative terminal side joint.

3. The fuse of claim 1,
wherein said positive terminal side joint has lower resistance than said negative terminal side joint.

4. The fuse of claim 1,
wherein said positive terminal side joint has a larger width than said negative terminal side joint.

5. The fuse of claim 1,
wherein said positive terminal side joint has a larger width at least in a region in the vicinity of said fusing part than said negative terminal side joint.

6. The fuse of claim 1,
wherein said fusing part, a positive terminal side connecting part that is a portion of said positive terminal side joint connected to said fusing part and a negative terminal side connecting part that is a portion of said negative terminal side joint connected to said fusing part are formed in an identical fuse layer,
said positive terminal side joint includes said positive terminal side connecting part, a positive terminal side interconnect layer formed above said positive terminal side connecting part and at least one positive terminal side contact for connecting said positive terminal side connecting part and said positive terminal side interconnect layer to each other, and
said negative terminal side joint includes said negative terminal side connecting part, a negative terminal side interconnect layer formed above said negative terminal side connecting part and at least one negative terminal side contact for connecting said negative terminal side connecting part and said negative terminal side interconnect layer to each other.

7. The fuse of claim 6,
wherein said fuse layer is made of polysilicon.

8. The fuse of claim 6,
wherein said positive terminal side contact has a larger area than said negative terminal side contact.

9. The fuse of claim 6,
wherein said positive terminal side joint further includes a silicide layer formed at least on said positive terminal side connecting part.

10. The fuse of claim 6,
wherein said positive terminal side interconnect layer is formed in a number of layers of two or more, and
said negative terminal side interconnect layer is formed in a smaller number of layers than said positive terminal side interconnect layer.

11. The fuse of claim 6,
wherein said positive terminal side joint further includes a heat dissipation layer formed above said positive terminal side connecting part.

12. The fuse of claim 11,
wherein said heat dissipation layer is formed in a number of layers of two or more.

13. A write method for a fuse composed of a fusing part to be fused through voltage application, a positive terminal side joint connected to one end of said fusing part and a negative terminal side joint connected to the other end of said fusing part, comprising a step of:
applying a voltage to said fuse by a write circuit including a protective resistance and a relay,
wherein, in the step of applying a voltage, a current limiting resistance is serially connected between said positive terminal side joint of said fuse and said relay and said voltage is applied to said fuse through said current limiting resistance, whereby fusing said fusing part with a current flowing to said fusing part limited within a given range.

14. The write method for a fuse of claim 13,
wherein said current limiting resistance is disposed in said write circuit.

15. The write method for a fuse of claim 13,
wherein said current limiting resistance is disposed outside said write circuit and in the same circuit area as said fuse.

16. The write method for a fuse of claim 13,
wherein at least said fusing part of said fuse is made of polysilicon.

17. The write method for a fuse of claim 13,
wherein said given range of said current is not less than 50 mA and not more than 100 mA.

18. The write method for a fuse of claim 13,
wherein said current limiting resistance has resistance not less than 10 Ω and not more than 600 Ω.
